(19) United States
(12) Patent Application Publication
(10) Pub. No.: US 2008/0111635 A1
(43) Pub. Date: May 15, 2008

(54) FRACTIONAL-N CONTROLLER WITH AUTOMATIC SWEPT FREQUENCY CHANGES

(76) Inventor: Brian M. Miller, Liberty Lake, WA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/551,990

(22) Filed: Oct. 23, 2006

(51) Int. Cl. H03L 7/00

(52) U.S. Cl. 331/16

(57) ABSTRACT

The invention is an enhancement for fractional-N based RF frequency synthesis to allow phase locked loops to switch output frequency more rapidly. An integrated fractional-N controller automatically sweeps from its current frequency to a new frequency when a new frequency is requested. Upon initialization, the fractional-N controller receives a value representing the desired sweep rate. This value is stored and used for all subsequent frequency changes. The automatic swept frequency feature accommodates new frequencies greater or less than the current frequency.

### BACKGROUND

FIG. 1 illustrates a prior art frequency multiplying phase lock loop (PLL). The output frequency, Fₒᵤₜ, is N times the input frequency Fᵢₙ. The output frequency of the PLL can be any integral multiple of Fᵢₙ.

Fractional divide ratios, N.f, may be achieved with a fractional-N PLL; where N is the integer portion of the divide number and f is the fractional component. E.g if the desired divide ratio is 100.63, N=100 and f=0.63. A typical fractional-N PLL is shown in FIG. 2. In operation, fractional-N controller 18 computes a new divide ratio Nₒᵤₜ(k) for each cycle of Fᵢₙ. The output of the fractional-N controller has 2 components. N is the integer portion of the desired fractional divide ratio. Δ(k) is an integer offset that is updated every cycle of Fᵢₙ. Δ(k) may be positive or negative and typically has a magnitude less than 7.

A fractional divide ratio is obtained by periodically altering Δ(k). To illustrate, if an effective divide ratio (N.f) of 10.1 is desired, N is set to 10. Δ(k) is set to 0 for 9 consecutive cycles of Fᵢₙ, then set to 1 for the 10^{th} cycle of Fᵢₙ. The average divide ratio over 10 cycles will be (10·9+11·1)/10=10.1. Δ(k) is toggled to achieve, on average, the desired fractional frequency.

Many applications have a need to switch from one frequency to a new frequency on a periodic or aperiodic basis. When a large frequency change is requested (somewhere on the order of 20× PLL BW) and the PLL attempts to drive the voltage controlled oscillator (VCO) tune line to the correct voltage, the PLL will often experience an interval of non-linear behavior due to a combination of limited voltage slew rate and/or voltage saturation, and phase lock is lost. Most PLLs automatically recover from this condition but the recovery is slow due to long time constants in the loop filter F(s), unexpected behavior from saturated amplifiers, and limited current or voltage drive.

The fastest switching speed is usually obtained when the PLL does not lose lock. Applications requiring fast switching speed often use ancillary circuitry which pre-tune the VCO, or temporarily alter the PLL bandwidth (BW), to enhance switching time by minimizing the period over which the PLL is out of lock.

### SUMMARY

Fast switching speed is obtained without extra circuitry by automatically sweeping the PLL from its current frequency to a new frequency, when a new frequency is requested. The fractional-N controller performs all calculations and operations required to sweep from the current frequency to the requested new frequency. After a one time initialization (typically at turn-on), the only information required by the fractional-N controller is the requested new frequency. During initialization, the fractional-N controller receives a value representing the optimum sweep rate. This value is stored and used for all subsequent frequency changes. The automatic swept frequency feature accommodates new frequencies greater or less than the current frequency.

### BRIEF DESCRIPTION OF THE DRAWINGS

FIG. 1 illustrates a prior art N controller.

FIG. 2 illustrates a prior art fractional-N controller.

FIG. 3 illustrates a process flowchart according to the invention.

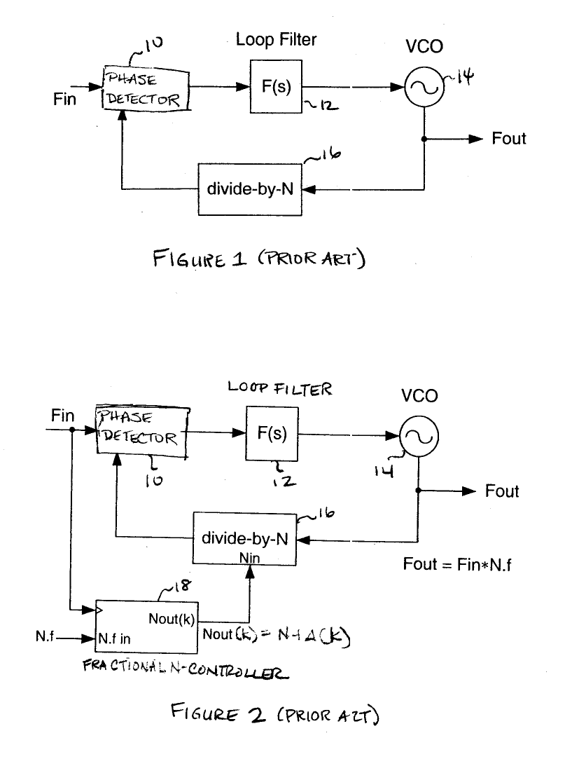

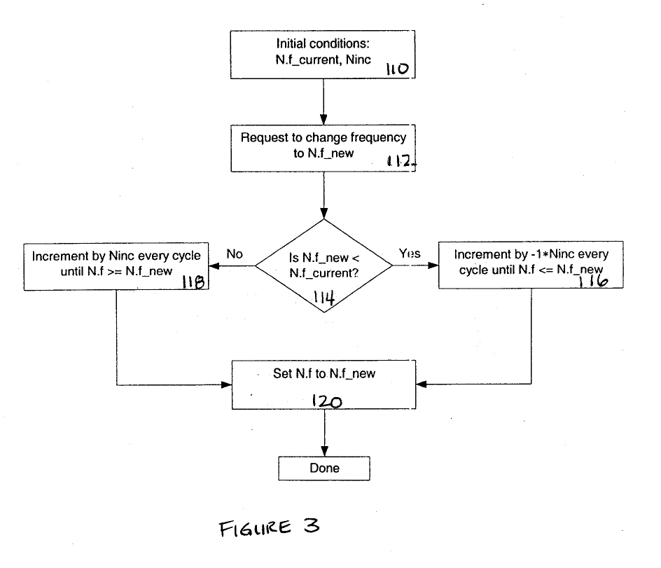

### DETAILED DESCRIPTION

Fractional-N PLLs can be designed to support frequency sweep. A frequency sweep is the act of performing a linear vs. time transition from an initial frequency, Fstart, to a final frequency, Fstop. The fine frequency resolution of the fractional-N loop makes this possible.

To illustrate, time is quantized to units of Tin (Tin=1/Fin), represented by k.

TABLE 1

| Fin = 10 MHz | |
|---|---|
| k = 0: N.f = 100 | Fout = N.f · Fin = 1000.0 MHz |
| k = 1: N.f = 100.01 | Fout = N.f · Fin = 1000.1 MHz |
| k = 2: N.f = 100.02 | Fout = N.f · Fin = 1000.2 MHz |
| k = 3: N.f = 100.03 | Fout = N.f · Fin = 1000.3 MHz |
| . . . | |
| k = 100: N.f = 101 | Fout = N.f · Fin = 1010.0 MHz |

The sweep is accomplished by incrementing the current frequency N.f, by a constant, e.g. 0.01, every cycle of Fin.

The invention is a method to automatically change the output frequency of a fractional-N PLL via a linear sweep instead of a step.

When fast switching speed is needed, it is imperative to prevent the PLL from losing lock. One way to accomplish this is to sweep the frequency from its current value to the desired value. The maximum rate at which a PLL can be linearly swept without losing lock can be calculated. Frequency switching speed is optimized when the PLL is swept to the new desired frequency at said maximum.

FIG. 3 illustrates a process flowchart according to the invention. Step 110 represents the initial conditions at entry to the algorithm. Ninc is the incremental frequency step which provides the optimal sweep rate and was set at tum-on. N.f_current is the current frequency and was previously established by the user or at turn-on. In step 112, a request to change frequency is received. N.f_new is the desired frequency. In step 1 14, it is determined if the new frequency is less than the current frequency. If yes, in step 116, the current frequency is decremented for each cycle, Fin, until the current frequency is less than or equal to the desired frequency. If no, in step 118, the current frequency is incremented for each cycle until the current frequency is greater than or equal to the desired frequency.

When step 120 is reached, the sweep has concluded. The likelihood of the difference between N.f_new and N.f_current being an integer multiple of Ninc is very small. Therefore multiple Ninc increments of N.f_current will not sum exactly to N.f_new and the sweep will overshoot the desired frequency when it terminates. The magnitude of the overshoot error will be less than one frequency increment (Ninc*Fin); a value which is small compared to the PLL BW. In step 120 the value of N.f, post sweep, is adjusted to equal the exact desired frequency, N.f_new. Performing this adjustment in a single step does not threaten PLL lock because the adjustment is so small.

The aforementioned method may be applied to analog corrected or Δσ Fractional-N phase lock loops.

I claim:

1. A system comprising:
a phase detector receiving an input signal;
a loop filter receiving the output of the phase detector;
a voltage controlled oscillator, receiving the output of the loop filter, generating a VCO output signal;
a N divider, receiving the VCO output signal, generating a divided output signal;
the phase detector receiving the divided output signal; and
a fractional-N controller, receiving a digital word that represents an effective divide ratio indicative of a desired frequency, receiving a sweep increment, automatically sweeping a current frequency to the desired frequency;
the N divider receiving the output of the fractional-N controller.

2. A system, as in claim 1, wherein the fractional-N controller including:
comparing the desired frequency with the current frequency;
periodically updating the current frequency by a sweep increment until it is within a tolerance of the desired frequency; and
setting the current frequency to the desired frequency.

3. A system, as in claim 2, wherein the desired frequency is greater than the current frequency, periodically updating the current frequency includes incrementing the current frequency.

4. A system, as in claim 2, wherein the desired frequency is less than the current frequency, periodically updating the current frequency includes decrementing the current frequency.
